(19) United States
(12) Patent Application Publication
(10) Pub. No.: US 2026/0250560 A1
(43) Pub. Date: Aug. 27, 2026

(54) RESIN COMPOSITION, AND INTER-LAYER INSULATING ADHESIVE FILM, LAMINATED CIRCUIT BOARD, ELECTRONIC COMPONENT, AND SEMICONDUCTOR DEVICE USING SAME

(71) Applicant: Namics Corporation, Niigata-shi, Niigata (JP)

(72) Inventor: Masaki Yoshida, Niigata (JP)

(73) Assignee: Namics Corporation, Niigata-shi, Niigata (JP)

(21) Appl. No.: 19/162,679

(22) PCT Filed: Feb. 6, 2024
(86) PCT No.: PCT/JP2024/003967

§ 371 Date: Sep. 5, 2025

(30) Foreign Application Priority Data
Mar. 6, 2023 (JP) 2023-033944

(51) Int. Cl. C09J 7/38; H10W 70/695

(52) U.S. Cl. CPC C09J 7/387; C09J 2203/326; C09J 2301/414; H10W 70/695

(57) ABSTRACT

A resin composition contains (A) a thermosetting resin having at least one of a vinylbenzyl group and a maleimide group; and (B) a compound having a butadiene skeleton having a 1,2 vinyl group. The component (B) has a number average molecular weight of 1,000 to 10,000. The resin composition may have a minimum melt viscosity of less than 40,000 Pa·s.

### TECHNICAL FIELD

The present invention relates to a resin composition, and an adhesive film for interlayer insulation, a laminated substrate, an electronic component, and a semiconductor device using the same.

### BACKGROUND ART

In recent years, a communication electronic device such as a mobile terminal such as a smartphone or a tablet, a communication base station, or an advanced driving assistant system (ADAS) has increased in communication speed and communication capacity, and a 5G communication network using a high frequency signal has been constructed. Further, studies on the use of higher frequency signals for 6G communication and the like have also become active. An electronic substrate is an essential component for such high frequency communication.

On the other hand, a general substrate material (for example, FR-4) may have a large transmission loss of an electric signal in high frequency communication. Therefore, a substrate material having a small transmission loss has been developed. Here, “FR-4” is an abbreviation of “flame retardant type 4”, and is a material obtained by impregnating a glass fiber cloth with an epoxy resin and performing a thermosetting treatment. In order to reduce the transmission loss of the substrate material, it is necessary to reduce a dielectric constant and a dielectric loss tangent of a copper clad laminated sheet and an adhesive film for interlayer insulation used for the substrate material. Hereinafter, the “adhesive film for interlayer insulation” may be simply referred to as an “interlayer adhesive film”.

In addition, a substrate used for such high frequency communication needs to be multilayered and highly integrated for weight reduction and size reduction.

For example, a polyphenylene ether resin composition containing polyphenylene ether and a styrene-butadiene block copolymer having a 1,2 vinyl structure has been proposed as a high frequency molding material (see, for example, Patent Literature 1). The polyphenylene ether resin composition disclosed in Patent Literature 1 is thought to be capable of improving heat resistance and water resistance while having low dielectric properties.

### CITATION LIST

### Patent Literature

Patent Literature 1: WO 2021/024679

### SUMMARY OF INVENTION

### Technical Problem

Regarding an adhesive film for a substrate for processing a high frequency signal, for example, in the case where an inorganic filler such as a silica filler is highly filled in a resin composition, there is a problem that a melt viscosity thereof increases and embeddability into the substrate deteriorates. For example, when the melt viscosity is high, it is difficult to perform embedment into a wiring pattern or the like in laminating and adhering the substrates.

Patent Literature 1 does not mention at all fluidity (in other words, embeddability into a substrate) required for the interlayer adhesive film. In addition, the polyphenylene ether resin composition evaluated in Patent Literature 1 is only methacryl-modified polyphenylene ether.

As a resin composition for use in high frequency communication, there is a strong demand for the development of a resin composition having good embeddability into a substrate while having low dielectric properties.

The present invention has been made in view of such problems in the related art. The present invention provides a resin composition having good embeddability into a substrate while having low dielectric properties. Further, the present invention provides an adhesive film for interlayer insulation, a laminated substrate, an electronic component, and a semiconductor device using such a resin composition.

### Solution to Problem

According to the present invention, there are provided the following resin composition, and an adhesive film for interlayer insulation, a laminated substrate, an electronic component, and a semiconductor device using the same.

[1]A resin composition containing: (A) a thermosetting resin having at least one of a vinylbenzyl group and a maleimide group; and (B) a compound having a butadiene skeleton having a 1,2 vinyl group, in which the component (B) has a number average molecular weight of 1,000 to 10,000.

[2] The resin composition according to the above [1], in which the resin composition has a minimum melt viscosity of less than 40,000 Pa·s.

[3] The resin composition according to the above [1] or [2], in which the component (A) is a thermosetting resin having a vinylbenzyl group at a terminal and having a polyphenylene skeleton.

[4] The resin composition according to any one of the above [1] to [3], in which the component (B) is a compound having a styrene skeleton.

[5] The resin composition according to any one of the above [1] to [4], in which the component (B) is a styrene-butadiene block copolymer.

[6] The resin composition according to any one of the above [1] to [5], in which the component (B) is a styrene-butadiene-styrene block copolymer represented by the following structural formula (1) or a hydrogenated product thereof.

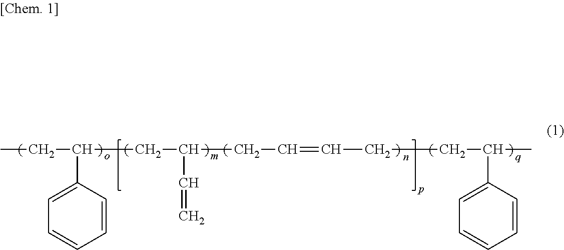

(In the structural formula (1), m, o, p, and q are each independently a positive integer, n is 0 or a positive integer, a relationship of o:p:q=(1 to 20):(60 to 98):(1 to 20) is satisfied, and a relationship of m:n=100:0 to 80:20 is satisfied.)

[7] The resin composition according to any one of the above [1] to [6], in which the butadiene skeleton of the component (B) contains 5 mass % to 95 mass % of a 1,2 vinyl structure.

[8] The resin composition according to any one of the above [1] to [7], further containing: (C) a thermoplastic elastomer component.

[9] The resin composition according to any one of the above [1] to [8], further containing: (D) a reaction accelerator component.

[10] The resin composition according to the above [9], in which the component (D) is an organic peroxide.

[11] The resin composition according to any one of the above [1] to [10], further containing: (E) an inorganic filler.

[12] The resin composition according to the above [11], in which the component (E) is contained in an amount of 50 mass % or more in 100 mass % of a non-volatile component in the resin composition.

[13] The resin composition according to the above [11], in which the component (E) is contained in an amount of 200 parts by mass or more with respect to 100 parts by mass as a total of the component (A) and the component (B).

[14] The resin composition according to any one of the above [1] to [13], in which the component (B) is contained in an amount of 10 to 200 parts by mass with respect to 100 parts by mass of the component (A).

[15] The resin composition according to any one of the above [1] to [14], in which the resin composition has a minimum melting temperature of lower than 200° C.

[16] An adhesive film for interlayer insulation, containing: the resin composition according to any one of the above [1] to [15].

[17]A laminated substrate containing: a cured product of the resin composition according to any one of the above [1] to [15] or a cured product of the adhesive film for interlayer insulation according to the above [16].

[18] An electronic component including: the laminated substrate according to the above [17].

[19]A semiconductor device including: the laminated substrate according to the above [17] or the electronic component according to the above [18].

### Advantageous Effects of Invention

The resin composition according to the present invention exhibits effects of excellent dielectric properties and excellent embeddability into a substrate. In particular, by containing a thermosetting resin having at least one of a vinylbenzyl group and a maleimide group as the component (A), the minimum melt viscosity can be lowered. That is, since the thermosetting resin as the component (A) has a high bonding energy, the reaction proceeds slowly, and as a result, it is thought that the minimum melt viscosity is lowered. In addition, the resin composition according to the present invention has excellent dielectric properties, adhesiveness, thermal expansion coefficient, and heat resistance reliability after thermal curing. In addition, since the compound having a butadiene skeleton having a 1,2 vinyl group as the component (B) has a number average molecular weight of 1,000 to 10,000, fluidity and the thermal expansion coefficient can be set to suitable values.

In addition, the adhesive film for interlayer insulation according to the present invention is composed of the resin composition according to the present invention, and exhibits effects of excellent dielectric properties and excellent embeddability. Further, the laminated substrate, the electronic component, and the semiconductor device according to the present invention contain a cured product of the resin composition or the adhesive film for interlayer insulation according to the present invention, and exhibit the effects of the present invention described above.

### DESCRIPTION OF EMBODIMENTS

Hereinafter, embodiments of the present invention will be described, but the present invention is not limited to the following embodiments. Therefore, it should be understood that the following embodiments to which modifications, improvements, and the like are appropriately added based on ordinary knowledge of those skilled in the art without departing from the gist of the present invention also fall within the scope of the present invention.

### [Resin Composition]

A resin composition according to a first embodiment of the present invention is a resin composition containing: (A) a thermosetting resin having at least one of a vinylbenzyl group and a maleimide group; and (B) a compound having a butadiene skeleton having a 1,2 vinyl group. Hereinafter, (A) the thermosetting resin having at least one of a vinylbenzyl group and a maleimide group may be referred to as a component (A). Similarly, (B) the compound having a butadiene skeleton having a 1,2 vinyl group may be referred to as a component (B). In the resin composition according to the present embodiment, the component (B) has a number average molecular weight of 1,000 to 10,000.

The resin composition according to the present embodiment has excellent dielectric properties and good embeddability into a substrate. In particular, by containing a thermosetting resin having at least one of a vinylbenzyl group and a maleimide group as the component (A), a minimum melt viscosity can be lowered. That is, since the thermosetting resin as the component (A) has a high bonding energy, the reaction proceeds slowly, and as a result, it is thought that the minimum melt viscosity is lowered. In addition, the resin composition according to the present invention has excellent dielectric properties, adhesiveness, thermal expansion coefficient, and heat resistance reliability after thermal curing. In addition, since the compound having a butadiene skeleton having a 1,2 vinyl group as the component (B) has a number average molecular weight of 1,000 to 10,000, fluidity and the thermal expansion coefficient can be set to suitable values.

Note that, the resin composition according to the present embodiment may contain other components such as a thermoplastic elastomer component (C), a reaction accelerator component (D), and an inorganic filler (E) in addition to the component (A) and the component (B) described above. Hereinafter, each of the components described above may be appropriately referred to as a component (C) to a component (E). Of course, the resin composition according to the present embodiment may further contain other resin components in addition to the component (C).

### [Component (A)]

The component (A) is a thermosetting resin having at least one of a vinylbenzyl group and a maleimide group. By containing the component (A), the minimum melt viscosity can be lowered. That is, since the thermosetting resin having at least one of a vinylbenzyl group and a maleimide group has a high bonding energy, the reaction proceeds slowly, and as a result, it is thought that the minimum melt viscosity is lowered. On the other hand, since a thermosetting resin having, for example, a methacryloyl group has a low bonding energy, the reaction rapidly proceeds, and as a result, it is estimated that the minimum melt viscosity is increased.

Examples of the thermosetting resin having a vinylbenzyl group as the component (A) include a thermosetting resin having a vinylbenzyl group at a terminal thereof. Examples of such a thermosetting resin include a thermosetting resin having a vinylbenzyl group at a terminal and having a polyphenylene skeleton.

Examples of the thermosetting resin having a vinylbenzyl group at a terminal and having a polyphenylene skeleton include a compound having a structure represented by the following general formula (2).

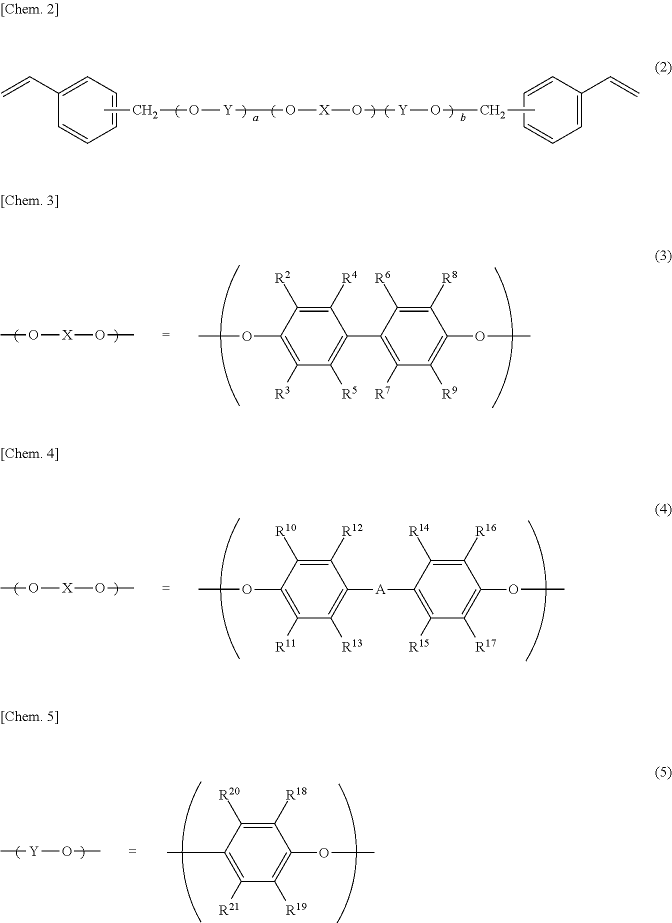

In the general formula (2), —(O—X—O) is represented by a structural formula (3) or (4).

In the structural formula (3), R², R³, R⁴, R⁸, and R⁹ are each an alkyl group having 6 or less carbon atoms or a phenyl group, and may be the same as or different from each other. R⁵, R⁶, and R⁷ are each a hydrogen atom, an alkyl group having 6 or less carbon atoms, or a phenyl group, and may be the same as or different from each other.

In the structural formula (4), R¹⁰, R¹¹, R¹², R¹³, R¹⁴, R¹⁵, R¹⁶, and R¹⁷ are each a hydrogen atom, an alkyl group having 6 or less carbon atoms, or a phenyl group, and may be the same as or different from each other. -A- represents a linear, branched, or cyclic divalent hydrocarbon group having 20 or less carbon atoms.

In the general formula (2), —(Y—O)— is represented by the structural formula (5). In —(Y—O)—, one kind of structure or two or more kinds of structures are randomly arranged. In the structural formula (5), R¹⁸ and R¹⁹ are each an alkyl group having 6 or less carbon atoms or a phenyl group, and may be the same as or different from each other. R²⁰ and R²¹ are each a hydrogen atom, an alkyl group having 6 or less carbon atoms, or a phenyl group, and may be the same as or different from each other.

In the general formula (2), a and b are each an integer of 0 to 100. At least one of a and b is not 0.

Examples of -A- in the structural formula (4) include divalent organic groups such as methylene, ethylidene, 1-methylethylidene, 1,1-propylidene, 1,4-phenylenebis(1-methylethylidene), 1,3-phenylenebis(1-methylethylidene), cyclohexylidene, phenylmethylene, naphthylmethylene, and 1-phenylethylidene. However, -A- in the structural formula (4) is not limited thereto.

The compound represented by the general formula (2) is preferably a compound in which R², R³, R⁴, R⁸, R⁹, R¹⁸, and R¹⁹ are each an alkyl group having 3 or less carbon atoms, and R⁵, R⁶, R⁷, R¹⁰, R¹¹, R¹², R¹³, R¹⁴, R¹⁵, R¹⁶, R¹⁷, R²⁰, and R²¹ are each a hydrogen atom or an alkyl group having 3 or less carbon atoms. In particular, it is more preferable that —(O—X—O)— represented by the structural formula (3) or the structural formula (4) is a compound represented by the following structural formula (6), structural formula (7), or structural formula (8). Similarly, particularly, it is more preferable that —(Y—O)— represented by the structural formula (5) is a compound represented by the following structural formula (9) or structural formula (10), or a structure in which the compound represented by the structural formula (9) and the compound represented by the structural formula (10) are randomly arranged.

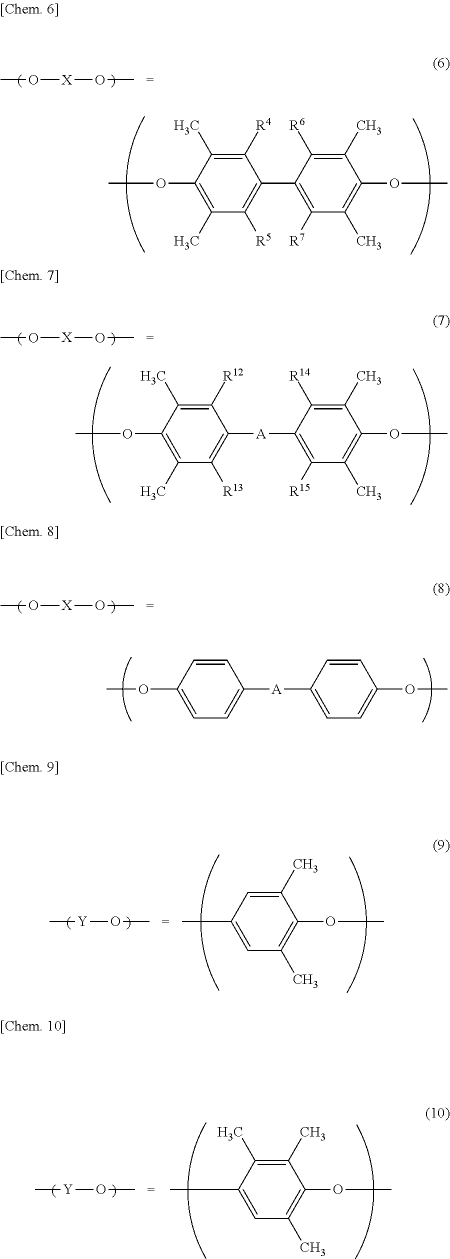

A method for producing the compound represented by the general formula (2) is not particularly limited. For example, the compound represented by the general formula (2) can be produced by the following method. First, a bifunctional phenol compound and a monofunctional phenol compound are oxidatively coupled to obtain a bifunctional phenylene ether oligomer. Next, a terminal phenolic hydroxy group in the obtained bifunctional phenylene ether oligomer is vinylbenzyl etherified. In this manner, the compound represented by the general formula (2) can be produced.

The compound represented by the general formula (2) has a number average molecular weight of preferably 1,000 to 3,000, more preferably 1,000 to 2,500, and particularly preferably 1,000 to 2,000. When the number average molecular weight of the compound represented by the general formula (2) is within the above numerical range, solubility, low dielectric properties, the fluidity, and heat resistance are made more excellent. For example, when the number average molecular weight is 1,000 or more, stickiness hardly occurs when the resin composition is formed into a coating film shape. When the number average molecular weight is 3,000 or less, a decrease in solubility of the resin composition in a solvent can be effectively prevented. In addition, when a compound having a number average molecular weight within the above numerical range is used as the component (A), curability and electrical properties of the resin composition at a high frequency are improved. Here, the number average molecular weight is a value obtained by gel permeation chromatography (GPC) using a calibration curve with standard polystyrene.

As the component (A), a compound represented by the general formula (2) may be used alone, or two or more kinds of compounds represented by the general formula (2) may be used in combination.

Examples of the thermosetting resin having a vinylbenzyl group at the terminal as the component (A) include trade names “OPE2St-2200” and “OPE2St-1200” manufactured by MITSUBISHI GAS CHEMICAL COMPANY, INC.

Examples of the thermosetting resin having a maleimide group as the component (A) include a thermosetting resin having a maleimide group at the terminal thereof.

The thermosetting resin having a maleimide group at the terminal used as the component (A) can be, for example, a compound having one or more maleimide groups in a molecule represented by the following general formula (11). A monomaleimide compound and a polymaleimide compound can be suitably used and are represented by the following general formula (11), (12), (13), (14) or (15).

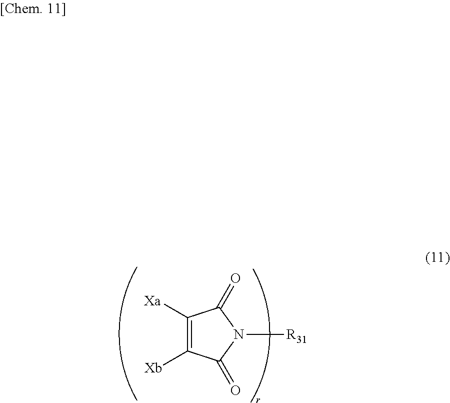

(In the general formula (11), R³¹ is a monovalent or polyvalent organic group, which is any one of aliphatic, alicyclic, aromatic, and heterocyclic groups having r valence. Xa and Xb are monovalent atoms or organic groups, which may be the same as or different from each other, selected from a hydrogen atom, a halogen atom, and an aliphatic organic group. Note that, r represents an integer of 1 or more.)

In the general formula (11), R³¹ is preferably phenyl, alkylphenyl, dialkylphenyl, alkoxyphenyl, benzyl, dodecyl, alkyl, or cycloalkyl. In addition, Xa and Xb are each preferably a hydrogen atom.

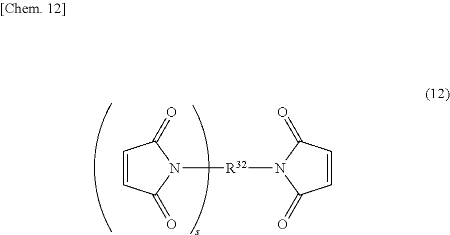

(In the general formula (12), R³² is a monovalent or divalent organic group, which is any one of aliphatic, alicyclic, aromatic, and heterocyclic group. s is 0 or 1.)

In the general formula (12), in the case where s is 0 and R³² is a monovalent group, it is preferably phenyl, alkylphenyl, dialkylphenyl, alkoxyphenyl, benzyl, dodecyl, alkyl, or cycloalkyl. In the general formula (12), in the case where s is 1 and R³² is a divalent group, it is preferably alkylene, fluorene, or cyclohexylene-alkylene-cyclohexylene.

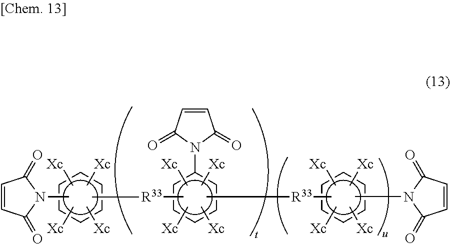

(In the general formula (13), R³³'s are each —C(Xc)₂-, —CO—, —O—, —S—, —SO₂— or a linking bond, and may be the same as or different from each other). Xc's each represent an alkyl group having 1 to 4 carbon atoms, —CF₃, —OCH₃, —NH₂, a halogen atom, or a hydrogen atom, which may be the same as or different from each other. Note that, in the general formula (13), the substitution positions of benzene rings are independent of each other. t and u each represent an integer of 0 or 1 to 10.)

Specific examples of the monomaleimide compound represented by the general formula (11) or (12) include N-phenylmaleimide, N-(2-methylphenyl)maleimide, N-(4-methylphenyl)maleimide, N-(2,6-dimethylphenyl)maleimide, N-(2,6-diethylphenyl)maleimide, N-(2-methoxyphenyl)maleimide, N-benzylmaleimide, N-dodecylmaleimide, N-isopropylmaleimide, and N-cyclohexylmaleimide.

Specific examples of the polymaleimide compound represented by the general formula (13) or (12) include 1,2-dimaleimidoethane, 1,3-dimaleimidopropane, bis(4-maleimidophenyl)methane, bis(3-ethyl-4-maleimidophenyl)methane, bis(3-ethyl-5-methyl-4-maleimidophenyl)methane, 2,7-dimaleimidofluorene, N,N′-(1,3-phenylene)bismaleimide, N,N′-(1,3-(4-methylphenylene)bismaleimide, bis(4-maleimidophenyl)sulfone, bis(4-maleimidophenyl)sulfide, bis(4-maleimidophenyl)ether, 1,3-bis(3-maleimidophenoxy)benzene, 1,3-bis(3-(3-maleimidophenoxy)phenoxy)benzene, bis(4-maleimidophenyl)ketone, 2,2-bis(4-(4-maleimidophenoxy)phenyl)propane, bis(4-(4-maleimidophenoxy)phenyl)sulfone, bis[4-(4-maleimidophenoxy)phenyl]sulfoxide, 4,4′-bis(3-maleimidophenoxy)biphenyl, 1,3-bis(2-(3-maleimidophenyl)propyl)benzene, 1,3-bis(1-(4-(3-maleimidophenoxy)phenyl)-1-propyl)benzene, bis(maleimidocyclohexyl)methane, 2,2-bis[4-(3-maleimidophenoxy)phenyl]-1,1,1,3,3,3-hexafluoropropane, bis(maleimidophenyl)thiophene, and aliphatic, alicyclic, aromatic, and heterocyclic polymaleimides such as those represented by the following general formulas (14) and (15) (each including an isomer).

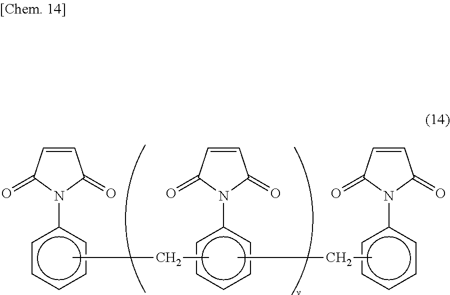

(In the general formula (14), v is 0 to 10 in terms of an average value.)

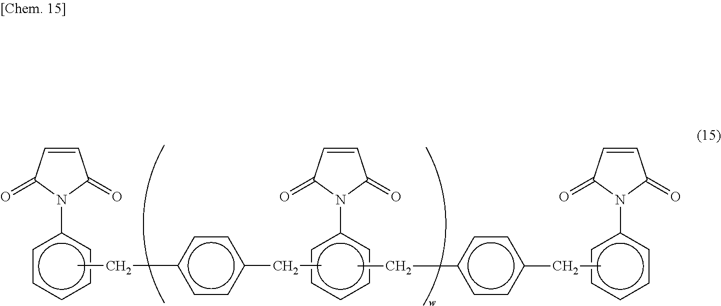

(In the general formula (15), w is 0 to 10 in terms of an average value.)

An aromatic polymaleimide is preferred from the viewpoint of moisture resistance, heat resistance, breaking strength, metal foil peel strength, and low thermal expansion properties when forming a printed wiring board. Among them, bis(3-ethyl-5-methyl-4-maleimidophenyl)methane is more preferred particularly from the viewpoint of further decreasing the thermal expansion coefficient, and 2,2-bis(4-(4-maleimidophenoxy)phenyl)propane is more preferred from the viewpoint of further increasing the breaking strength and the metal foil peel strength.

In addition, a monomaleimide that causes a gentle curing reaction is preferred from the viewpoint of improving moldability when forming an adhesive film. Among them, N-phenylmaleimide is more preferred in terms of cost. The maleimide compound may be used alone or in combination of two or more kinds thereof, or at least one kind or more of the maleimide compound and one or more kinds of crosslinking agents may be used in combination.

In the case of using the maleimide compound and another crosslinking agent in combination, a ratio of the maleimide compound in the component (A) is preferably 50 mass % or more, and more preferably 80 mass % or more. However, the maleimide compound is more preferably used alone than being used in combination with another crosslinking agent.

In addition, the thermosetting resin having a maleimide group at the terminal used as the component (A) may be, for example, a maleimide compound represented by the following general formula (16).

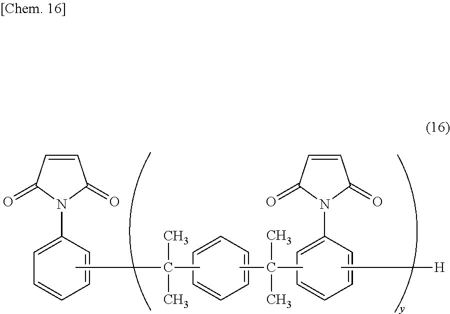

(In the general formula (16), y is the number of repetitions, and 1<y<5.)

A content of N,N′-(phenylene-di-(2,2-propylidene)-di-p-phenylene)bismaleimide in the maleimide compound represented by the general formula (16) is usually 90 area % or less, preferably 10 area % to 80 area %, more preferably 20 area % to 80 area %, and still more preferably 30 area % to 70 area %, as determined by GPC analysis (RI). When the content of N,N′-(phenylene-di-(2,2-propylidene)-di-p-phenylene)bismaleimide is 90 area % or less, the crystallinity decreases, and thus the solubility in a solvent is improved. On the other hand, the lower limit value of N,N′-(phenylene-di-(2,2-propylidene)-di-p-phenylene)bismaleimide may be 0 area %, and when it is 10 area % or more, a decrease in reactivity can be prevented.

A content in the case of y=1 in the maleimide compound represented by the general formula (16) is preferably 98 area % or less, more preferably 20 area % to 98 area %, still more preferably 30 area % to 90 area %, and particularly preferably 40 area % to 80 area %, as determined by GPC analysis (RI). When the content in the case of y=1 is 98 area % or less, the heat resistance is improved. On the other hand, the lower limit value in the case of y=1 may be 0 area %, and when it is 20 area % or more, a viscosity of a resin solution decreases, and an impregnation property is improved.

The maleimide compound represented by the general formula (16) has a softening point of preferably 50° C. to 150° C., more preferably 80° C. to 120° C., still more preferably 90° C. to 110° C., and particularly preferably 95° C. to 100° C. In addition, a melt viscosity at 150° C. is 0.05 Pa·s to 100 Pa·s, and preferably 0.1 Pa·s to 40 Pa·s.

The maleimide compound represented by the general formula (16) more preferably has a structure represented by the following general formula (17). This is because the crystallinity is lower than in the case where a substitution position of a propyl group with respect to the benzene ring to which the maleimide group is not bonded is at the para position in the general formula (16).

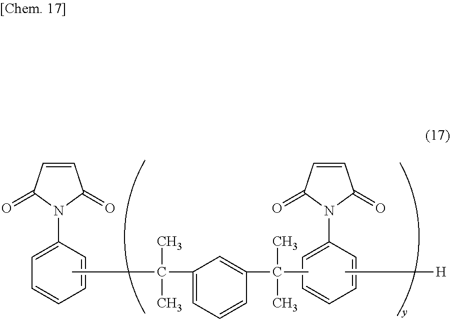

(In the general formula (17), y is the number of repetitions, and 1<y<5.)

The maleimide compound as the component (A) described above has a number average molecular weight of preferably 400 to 3,000, and more preferably 700 to 2,500. When the number average molecular weight of the maleimide compound is within the above numerical range, the solubility, the low dielectric properties, the fluidity, and the heat resistance are made more excellent. Here, the number average molecular weight of the maleimide compound is a value obtained by gel permeation chromatography (GPC) using a calibration curve with standard polystyrene.

As the maleimide compound as the component (A), the maleimide compound described above may be used alone, or two or more kinds of compounds may be used in combination.

Examples of the thermosetting resin having a maleimide group as the component (A) include a maleimide resin (trade name “BMI70”) manufactured by K I Chemical Industry Co., LTD., and a maleimide resin (trade name “MIR-5000-60T”) manufactured by Nippon Kayaku Co., Ltd.

### [Component (B)]

The component (B) is a compound having a butadiene skeleton having a 1,2 vinyl group. By containing the component (B), the adhesiveness can be improved. In particular, a butadiene-containing resin having a 1,2 vinyl group has a structure of a copolymer or a block copolymer with styrene, thereby achieving more excellent adhesiveness. In addition, the compound having a butadiene skeleton having a 1,2 vinyl group as the component (B) has a number average molecular weight of 1,000 to 10,000. With such a number average molecular weight, the fluidity and the thermal expansion coefficient can be improved. Here, the number average molecular weight of the compound as the component (B) is a value obtained by gel permeation chromatography (GPC) using a calibration curve with standard polystyrene.

Examples of the compound as the component (B) include the following component (B1), component (B2), and component (B3).

The component (B1) is a butadiene copolymer having a 1,2 vinyl group. For example, by using such a component (B1), the amount of monomer used can be reduced, and for example, a suitable cured body can be obtained without using a monomer. On the other hand, since the butadiene copolymer having a 1,2 vinyl group does not have a styrene skeleton, adhesion (particularly, peel strength of a roughened surface (M surface)) tends to be weak. Such a butadiene copolymer is not particularly limited as long as it has a 1,2 vinyl group and has a number average molecular weight of 1,000 to 10,000.

Examples of the component (B1) include a 1,2-polybutadiene homopolymer (trade names “B-3000” and “B-1000”) manufactured by NIPPON SODA CO., LTD., and a partially hydrogenated product (trade name “BI-3015”).

The component (B2) is a styrene-butadiene block copolymer having a 1,2 vinyl structure. For example, by using such a component (B2), the peel strength can be improved and the thermal expansion coefficient can be reduced.

The component (B2) is a block copolymer containing a butadiene block and a styrene block. The styrene block is a block obtained by polymerizing styrene, and the butadiene block is a block obtained by polymerizing butadiene. Such a styrene-butadiene block copolymer is not particularly limited as long as it has a 1,2 vinyl group and has a number average molecular weight of 1,000 to 10,000. The butadiene block is composed of only a 1,2 bond structure represented by the following formula (18), or composed of a 1,2 bond structure represented by the formula (18) and a 1,4 bond structure represented by the formula (19).

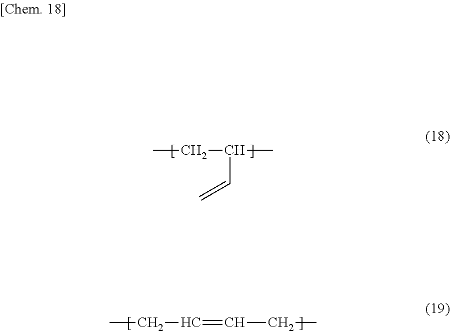

A molar ratio of the 1,2 bond structure represented by the formula (18) to the 1,4 bond structure represented by the formula (19) contained in the styrene-butadiene block copolymer having a 1,2 vinyl structure as the component (B2) is preferably 80:20 to 100:0.

A weight ratio of the styrene block to the butadiene block in the component (B2) is not particularly limited, and examples thereof include 10:90 to 80:20, 10:90 to 70:30, 10:90 to 60:40, 10:90 to 50:50, 20:80 to 80:20, 30:70 to 80:20, and 40:60 to 80:20. Among them, the ratio is preferably 10:90 to 80:20, 10:90 to 70:30, 10:90 to 60:40, and 10:90 to 50:50, and more preferably 10:90 to 50:50.

The component (B2) is preferably a styrene-butadiene-styrene block copolymer represented by the following structural formula (1) or a hydrogenated product thereof.

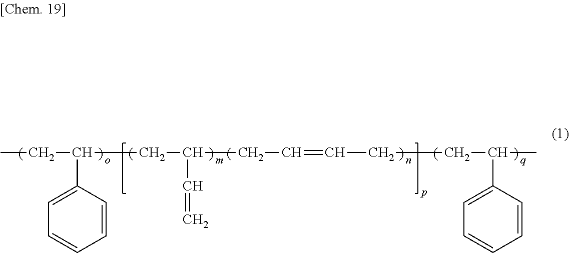

(In the structural formula (1), m, o, p, and q are each independently a positive integer, n is 0 or a positive integer, a relationship of o:p:q=(1 to 20):(60 to 98):(1 to 20) is satisfied, and a relationship of m:n=100:0 to 80:20 is satisfied.)

By using the styrene-butadiene-styrene block copolymer represented by the structural formula (1) as the component (B), the peel strength can be improved and the thermal expansion coefficient can be reduced.

A method for producing the component (B2) is not particularly limited, and for example, the styrene-butadiene-styrene block copolymer can be produced by a method described in JP-H06-192502A, JP-2000-514122A, JP-2007-302901A, or the like, or a method equivalent thereto.

Examples of the component (B2) include trade names “1,2-SBS-L42” and “1,2-H-SBS-L” manufactured by NIPPON SODA CO., LTD.

The component (B3) is a styrene-butadiene copolymer having a 1,2 vinyl group. Such a styrene-butadiene copolymer is not particularly limited as long as it has a 1,2 vinyl group and has a number average molecular weight of 1,000 to 10,000. Such a styrene-butadiene copolymer is hydrophobic and has a small number of polar groups. Therefore, low dielectric properties can be improved by adding it to the resin composition. Further, since the molecular weight is relatively small, the styrene-butadiene copolymer has a hydrophobic skeleton, and exhibits high solubility not only in a nonpolar organic solvent such as toluene but also in a polar organic solvent such as methyl ethyl ketone. Therefore, there is an advantage that the styrene-butadiene copolymer is easily dissolved in various solvents when forming a resin composition, and has excellent varnish stability in the case of being dissolved in a solvent to form a resin varnish. On the other hand, since the component (B3) is not a block copolymer but a random copolymer, the adhesion (peel strength of a glossy surface (S surface)) tends to be weak. That is, when the phenyl group is not arranged, it is presumed that the strength in a plane is hardly exhibited.

In addition, since the styrene-butadiene copolymer is in a liquid state, there is also an advantage that flexibility of the resin composition is improved, and handling properties (powder falling or the like) of the resin composition in a semi-cured state is improved (prevented).

The component (B3) is particularly preferably a styrene-butadiene copolymer having a crosslinkable 1,2-vinyl in the molecule, and thereby has reactivity as compared with a general styrene-butadiene polymer having many 1,4-bonds in the main chain. In addition, since the number average molecular weight is as low as 10,000 or less, it is thought that the reactivity of the 1,2-vinyl group in the styrene-butadiene copolymer is also further improved. Therefore, it is thought that the component (B3) contributes to the curing reaction and the resin has an excellent appearance after molding without bleeding.

More specifically, examples of the component (B3) include a styrene-butadiene copolymer having a structure represented by the following formula (20).

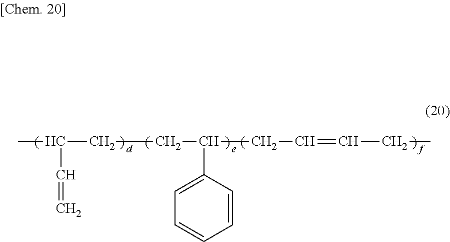

The formula (20) is an example of the styrene-butadiene copolymer, and in the formula (20), d represents a 1,2 vinyl group, e represents a styrene group, and f represents a 1,4-bond.

Examples of a structural unit having a 1,2 vinyl group include a structural unit represented by the following formula (21). Examples of a structural unit having a 1,4-bond include a structural unit represented by the following formula (22). Further, examples of the styrene group include a structural unit represented by the following formula (23).

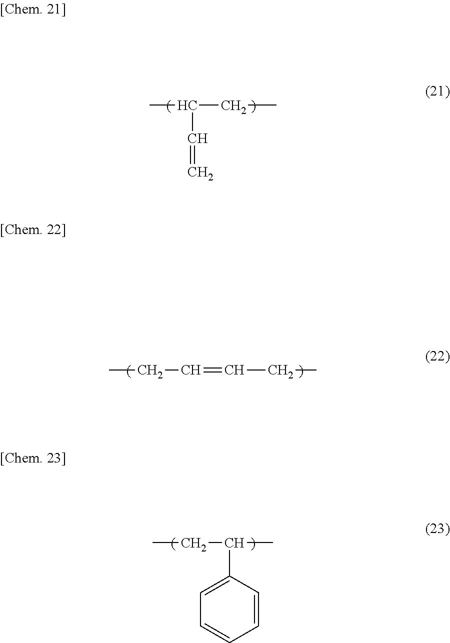

The styrene-butadiene copolymer having a 1,2-vinyl group preferably has a repeating structure of the structural unit represented by the formula (21) and a repeating structure of the structural unit represented by the formula (23). Further, a repeating structure of the structural unit represented by the formula (22) may be included.

In the styrene-butadiene copolymer as the component (B3), preferably, a styrene content in the molecule is 50 mass % or less and a butadiene content is 50 mass % or more, and more preferably, the styrene content is 20 mass % to 50 mass % and the butadiene content is 50 mass % to 80 mass %. That is, a relationship among d, e, and f shown in the above formula (20) is preferably expressed by:

$$e / ( d + e + f ) = 20 \% to 50 \%$$

$$( d + f ) / ( d + e + f ) = 50 \% to 80 \%$$

It is thought that when the styrene content is within the above range, a resin composition having a good balance between high Tg and excellent adhesion can be obtained. In addition, it is thought that when the butadiene content is within the above range, an elastic modulus of the resin composition can be reliably reduced, and thus the thermal expansion coefficient in a plane direction when forming a laminated sheet can be reduced. When the thermal expansion coefficient in the plane direction can be reduced, substrate warpage in a package substrate or the like can be reduced. The styrene content and the butadiene content in the styrene-butadiene copolymer can be measured by, for example, nuclear magnetic resonance spectroscopy (NMR).

Examples of the styrene-butadiene copolymer as the component (B3) include trade names “Ricon181” and “Ricon100” manufactured by CRAY VALLEY.

The compound as the component (B) is preferably a compound having a styrene skeleton. For example, among the component (B1), the component (B2), and the component (B3) described above, a styrene-butadiene block copolymer having a 1,2 vinyl structure as the component (B2) is more preferred from the viewpoint of the thermal expansion coefficient, adhesion strength, and the heat resistance reliability.

The number average molecular weight of the component (B) is not particularly limited as long as it is 1,000 to 10,000, and is, for example, preferably 1,000 to 8,000, more preferably 1,000 to 5,000, and particularly preferably 3,500 to 5,000. Note that, when measuring the number average molecular weight of a film composed of the resin composition, for example, it is sufficient that the film is dissolved in a solvent, and the number average molecular weight of the component dissolved in the solvent is measured.

The 1,2 vinyl structure in the butadiene skeleton of the compound as the component (B) is preferably 5 mass % to 95 mass %, more preferably 10 mass % to 95 mass %, and particularly preferably 20 mass % to 95 mass %. The 1,2 vinyl structure in the butadiene skeleton being within the above numerical range is advantageous in reducing the minimum melt viscosity. Examples of such a compound include a butadiene resin having 5 mass % to 95 mass % of a 1,2 vinyl structure. The content ratio of the 1,2 vinyl structure can be measured by FT-IR, NMR, or the like.

A content of the component (B) is preferably 10 to 200 parts by mass with respect to 100 parts by mass of the component (A). Such a configuration is advantageous in terms of heat resistance and chemical resistance due to a reaction with the component (A). Note that, although not particularly limited, the content of the component (B) is more preferably 15 to 190 parts by mass, and still more preferably 20 to 100 parts by mass, with respect to 100 parts by mass of the component (A).

### [Component (C)]

The component (C) is a thermoplastic elastomer component. The thermoplastic elastomer component is preferably, for example, a styrene-based thermoplastic elastomer or a hydrogenated styrene-based thermoplastic elastomer. Here, the hydrogenated styrene-based thermoplastic elastomer refers to a styrene-based thermoplastic elastomer subjected to hydrogenation, and examples of the hydrogenated styrene-based thermoplastic elastomer include a styrene/butadiene/butylene/styrene block copolymer (partially hydrogenated, SBBS) and a styrene/ethylene/butylene/styrene block copolymer (completely hydrogenated, SEBS). By using the hydrogenated styrene-based thermoplastic elastomer, the dielectric properties can be improved. Note that, in the case where the component (C) is a styrene-based thermoplastic elastomer, a styrene ratio in the component (C) is preferably 10% to 50%, more preferably 15% to 40%, and still more preferably 20% to 35%. When the styrene ratio in the component (C) is within the above numerical range, film formability and workability are excellent.

The thermoplastic elastomer component as the component (C) is not particularly limited, and is preferably a styrene/ethylene/butylene/styrene block copolymer (SEBS). When the component (C) is a styrene/ethylene/butylene/styrene block copolymer (SEBS), the heat resistance and film properties are excellent.

A number average molecular weight of the thermoplastic elastomer component as the component (C) is not particularly limited, and is, for example, preferably 10,000 to 1,000,000, more preferably 20,000 to 500,000, and particularly preferably 20,000 to 200,000. Note that, in the case where the component (C) is a compound having a butadiene skeleton having a 1,2 vinyl group, the number average molecular weight of the component (C) is more than 10,000.

A content of the component (C) is not particularly limited, and for example, the content of the component (C) is preferably 10 to 150 parts by mass, and more preferably 15 to 100 parts by mass, with respect to 100 parts by mass as a total of the component (A) and the component (B). When the content of the component (C) is within this range, the heat resistance and the film properties, which are the effects of containing the component (C), are more excellent.

### [Component (D)]

The component (D) is a reaction accelerator component. The reaction accelerator component as the component (D) is an additive for accelerating a reaction between the component (A) and the component (B). By containing such a component (D), a reaction initiation temperature shifts to a low temperature side, and curing of the resin composition is promoted.

The reaction accelerator component as the component (D) may be any component that accelerates the reaction between the component (A) and the component (B), and a known reaction accelerator component can be used. Examples of the reaction accelerator component include an organic peroxide, an inorganic peroxide, and an azo-based compound. The reaction accelerator component as the component (D) is preferably an organic peroxide.

As the organic peroxide, the following can be used: diacyl peroxides such as benzoyl peroxide, isobutyryl peroxide, isononanoyl peroxide, decanoyl peroxide, lauroyl peroxide, parachlorobenzoyl peroxide, and di(3,5,5-trimethylhexanoyl) peroxide; peroxyketals such as 2,2-di(4,4-di-(di-tert-butylperoxy)cyclohexyl)propane; peroxydicarbonates such as isopropyl purged carbonate, di-sec-butyl purged carbonate, di-2-ethylhexyl purged carbonate, di-1-methylheptyl purged carbonate, di-3-methoxybutyl purged carbonate, and dicyclohexyl purged carbonate; peroxy esters such as tert-butyl perbenzoate, tert-butyl peracetate, tert-butyl per-2-ethylhexanoate, tert-butyl perisobutyrate, tert-butyl perpivalate, tert-butyl diperadipate, cumyl pemeodecanoate, tert-butyl peroxybenzoate, and 2,5-dimethyl-2,5-di(benzoylperoxy)hexane; ketone peroxides such as methyl ethyl ketone peroxide and cyclohexanone peroxide; dialkyl peroxides such as di-tert-butyl peroxide, dicumyl peroxide, tert-butylcumyl peroxide, 2,5-dimethyl-2,5-di(t-butylperoxy)hexane, 2,5-dimethyl-2,5-di(t-butylperoxy)hexyne-3, 1,1-di(t-hexylperoxy)-3,3,5-trimethylcyclohexane, di-tert-hexyl peroxide, and di(2-tert-butylperoxyisopropyl)benzene; and hydroperoxides such as cumene hydroxyperoxide, tert-butyl hydroperoxide, and p-menthahydroperoxide. The organic peroxide to be used is not particularly limited, and when curing the resin composition, for example, a drying step at about 60° C. to 80° C. is often required, and thus an organic peroxide having a 10-hour half-life temperature of 100° C. to 140° C. is preferably used. Further, an organic peroxide having 10-hour half-life temperature of 110° C. to 130° C. is more preferred.

Examples of the organic peroxide as the component (D) include organic peroxides manufactured by NOF Corporation, trade name “PERCUMYL D” and trade name “PERBUTYL C”. As the component (D), one kind may be used alone, or two or more kinds may be used in combination.

In addition, in the case of containing the component (D), a content of the component (D) is preferably 0.1 to 5.0 parts by mass, and more preferably 0.5 to 3.0 parts by mass, with respect to 100 parts by mass of a resin component in the composition. With such a configuration, it is possible to favorably improve the heat resistance and the adhesiveness.

### [Component (E)]

The component (E) is an inorganic filler. The inorganic filler is required to have insulating properties and a small thermal expansion coefficient. As the inorganic filler, a general inorganic filler can be used.

Examples of the inorganic filler include silica, alumina, aluminum nitride, calcium carbonate, aluminum silicate, magnesium silicate, magnesium carbonate, barium sulfate, barium carbonate, lime sulfate, aluminum hydroxide, calcium silicate, potassium titanate, titanium oxide, zinc oxide, silicon carbide, silicon nitride, and boron nitride. The inorganic filler may be used alone or in combination of two or more kinds thereof. In particular, a silica filler and an alumina filler are preferred from the viewpoint of the insulating properties. A silica filler is preferred from the viewpoint of the dielectric properties and the thermal expansion coefficient. The inorganic filler may be surface-treated with a silane coupling agent having one or more functional groups selected from acrylic, methacrylic, styryl, amino, epoxy, and vinyl. For example, the inorganic filler is preferably surface-treated with a surface treatment agent such as an aminosilane-based coupling agent, a ureidosilane-based coupling agent, an epoxysilane-based coupling agent, a mercaptosilane-based coupling agent, a silane-based coupling agent, a vinylsilane-based coupling agent, a styrylsilane-based coupling agent, an acrylate silane-based coupling agent, an isocyanate silane-based coupling agent, a sulfide silane-based coupling agent, an organosilazane compound, or a titanate-based coupling agent to improve the heat resistance, moisture resistance, and dispersibility. These may be used alone or in combination of two or more kinds thereof. More preferably, among the surface-treated silica fillers, it is preferable to use a silica filler surface-treated with a vinylsilane-based coupling agent. By using a silica filler surface-treated with a vinylsilane-based coupling agent, the thermal expansion coefficient can be improved.

A shape of the inorganic filler is not particularly limited, and examples thereof include a spherical shape, a flake shape, a needle shape, and an amorphous shape. From the viewpoint of fluidity, a spherical shape is preferred. An average particle diameter is preferably 0.1 μm to 10 μm, and more preferably 0.1 μm to 4 μm. When the average particle diameter of the inorganic filler is within this range, the embeddability between fine structures is excellent. The average particle diameter is a particle diameter at an integrated value of 50% in a volume-based particle size distribution measured by a laser diffraction/scattering method. The average particle diameter can be measured by, for example, a laser scattering diffraction particle size distribution analyzer: LS13320 (wet, manufactured by Beckman Coulter, Inc.).

In the case where the resin composition contains the component (E), a content of the component (E) is preferably 50 mass % or more, more preferably 50 mass % to 90 mass %, and still more preferably 50 mass % to 85 mass % in 100 mass % of a non-volatile component in the resin composition. In the case where the content of the component (E) is defined as a ratio with respect to a total amount of the component (A) and the component (B), the content of the component (E) is preferably 200 parts by mass or more, more preferably 200 to 900 parts by mass, and still more preferably 400 to 900 parts by mass, with respect to 100 parts by mass as the total amount of the component (A) and the component (B). With such a configuration, the thermal expansion coefficient can be improved.

### Other Components

The resin composition according to the present embodiment may further contain components other than the component (A) to component (E) described above. Examples of other components include various additives such as a solvent, a silane coupling agent, a flame retardant, and a pigment. In addition to the component (A) to component (C), other compounds (for example, other resin components) may be further contained. Examples of other resin components include isocyanuric acid (diallylated isocyanuric acid derivative) from the viewpoint of further improving the embeddability into a substrate, and examples of commercially available products include “L-DAIC” (trade name) manufactured by SHIKOKU CHEMICALS CORPORATION.

### [Properties of Resin Composition]

The resin composition according to the present embodiment preferably has, for example, the following properties. The resin composition preferably has a minimum melt viscosity of less than 40,000 Pa·s. With such a configuration, the embeddability into a substrate is extremely good.

In the case where the resin composition does not contain an inorganic filler as the component (E), the minimum melt viscosity of the resin composition is more preferably 10 Pa·s or more and less than 40,000 Pa·s, still more preferably 100 Pa·s or more and less than 30,000 Pa·s, and particularly preferably 1,000 Pa·s or more and less than 10,000 Pa·s. Note that, even in the case where the content ratio of the component (E) is less than 50 mass % in 100 mass % of the non-volatile component in the resin composition, the minimum melt viscosity of the resin composition is more preferably 10 Pa·s or more and less than 40,000 Pa·s, and still more preferably 100 Pa·s or more and less than 30,000 Pa·s as in the case described above.

On the other hand, in the case where the content ratio of the component (E) is 50 mass % or more in 100 mass % of the non-volatile component in the resin composition, the minimum melt viscosity of the resin composition is more preferably 100 Pa·s or more and less than 40,000 Pa·s, still more preferably 1,000 Pa·s or more and less than 40,000 Pa·s, and particularly preferably 5,000 Pa·s or more and less than 30,000 Pa·s.

The resin composition has a minimum melting temperature of preferably lower than 200° C., more preferably 80° C. or higher and lower than 200° C., and still more preferably 100° C. or higher and lower than 180° C.

The minimum melt viscosity (Pa·s) and the minimum melting temperature (° C.) of the resin composition can be measured by the following method. First, a solution containing a resin composition is applied onto a release-treated PET film by a knife method. Thereafter, the solution on the PET film is continuously dried at a temperature of 80° C. for 2 minutes, at 100° C. for 2 minutes, and at 130° C. for 2 minutes to prepare a resin film having a thickness of 50 μm. The resin film thus prepared is laminated so as to have a thickness of 300 μm, and the melt viscosity is measured by a rheometer. The minimum melt viscosity and the minimum melting temperature at this time are read, and the read values are defined as the minimum melt viscosity (Pa·s) and the minimum melting temperature (° C.) of the resin composition. The measurement is performed using a parallel plate having a diameter of 5 mm under conditions of a load of 50 gf, a strain of 1%, a frequency of 10 Hz, and a temperature range of 50° C. to 200° C. at 5° C./min. The solution (solution containing the resin composition) to be applied onto the PET film can be prepared by dissolving each component constituting the resin composition in toluene as a solvent. At this time, in the case where the resin composition does not contain an inorganic filler as the component (E), the solution is prepared such that a solid content concentration in the solution is 30 mass %. On the other hand, in the case where the resin composition contains an inorganic filler as the component (E), each component is dissolved and dispersed such that the solid content concentration in the solution is 60 mass % to prepare a solution.

### [Method for Producing Resin Composition]

The resin composition according to the present embodiment can be produced by a known method. The resin composition according to the present embodiment can be produced by mixing the components described above using, for example, a grinding machine, a pot mill, a three-roll mill, a rotary mixer, or a twin-screw mixer.

### [Application of Resin Composition]

The resin composition according to the present embodiment can be suitably used as a resin composition for an adhesive or an adhesive film used for an electronic component. In addition, the resin composition according to the present embodiment can also be suitably used as an interlayer bonding sheet or an interlayer adhesive for a multilayer wiring board. In particular, the resin composition according to the present embodiment can be suitably used as an adhesive film for interlayer insulation. In the case where the resin composition according to the present embodiment is used for various applications for electronic components, the electronic components to be adhered are not particularly limited, and examples thereof include various printed wiring boards such as a ceramic substrate and an organic substrate, semiconductor chips, and semiconductor devices. In addition, the resin composition according to the present embodiment can also be suitably used as a dielectric layer in a rewiring layer of a fan-out wafer level package (FO-WLP).

An adhesive film or an interlayer adhesive for interlayer insulation using the resin composition according to the present embodiment is included in the form of a cured product of the resin composition in a laminated substrate or a semiconductor device constituting an electronic component or the like. Therefore, a laminated substrate or a semiconductor device constituting an electronic component or the like preferably contains a cured product of the resin composition according to the present embodiment.

Further, the resin composition according to the present embodiment can also be used as a prepreg using a cured product of the resin composition or as a high-frequency electronic component containing a cured product of the resin composition.

### EXAMPLES

Hereinafter, the present invention will be described in more detail with reference to Examples, but the present invention is not limited to these Examples. In the following Examples, “parts” and “%” represent “parts by mass” and” mass %”, respectively, unless otherwise specified.

### Examples 1 to 17 and Comparative Examples 1 to 7

### [Preparation of Sample]

Each component was weighed and blended at a blending ratio (part by mass) shown in Tables 1 to 4 below, and then dissolved in toluene as a solvent to prepare solutions containing resin compositions in Examples 1 to 17 and Comparative Examples 1 to 7. Note that, in the case where the resin composition did not contain an inorganic filler as the component (E) in the solution, the solution was prepared such that the solid content concentration in the solution was 30 mass %. On the other hand, in the case where the resin composition contained an inorganic filler as the component (E), each component was dissolved and dispersed such that the solid content concentration in the solution was 60 mass % to prepare a solution.

The raw materials used in the preparation of the solutions containing the resin compositions in Examples 1 to 17 and Comparative Examples 1 to 7 are as follows.

### [Component (A)]

A1(1): trade name “OPE2St-2200” manufactured by MITSUBISHI GAS CHEMICAL COMPANY, INC., number average molecular weight (Mn)=2200, modified polyphenylene ether resin having a vinylbenzyl group at terminal.

A1(2): trade name “OPE2St-1200” manufactured by MITSUBISHI GAS CHEMICAL COMPANY, INC., number average molecular weight (Mn)=1200, modified polyphenylene ether resin having a vinylbenzyl group at terminal.

A2(1): trade name “BMI70” manufactured by K I Chemical Industry Co., LTD., maleimide resin.

A2(2): trade name “MIR-5000-60T” manufactured by Nippon Kayaku Co., Ltd., maleimide resin (solid content: 60%, toluene solution).

### [Component (A′)]

A1′: trade name “SA-9000” manufactured by SABIC, number average molecular weight (Mn)=1700, modified polyphenylene ether resin having a methacrylic group at terminal.

### [Component (B)]

BT(1): trade name “B-1000” manufactured by NIPPON SODA CO., LTD., number average molecular weight (Mn)=1200, butadiene resin (1,2 vinyl structure: 85%).

BT(2): trade name “B-3000” manufactured by NIPPON SODA CO., LTD., number average molecular weight (Mn)=3200, butadiene resin (1,2 vinyl structure: 92%).

B1(3): trade name “BI-3015” manufactured by NIPPON SODA CO., LTD., number average molecular weight (Mn)=3200, butadiene resin (1,2 vinyl structure: 7%).

B2(1): trade name “1,2-SBS-L42” manufactured by NIPPON SODA CO., LTD., number average molecular weight (Mn)=4300, styrene-butadiene block copolymer (styrene: 20%, 1,2 vinyl structure: 90%).

B2(2): trade name “1,2-H-SBS-L” manufactured by NIPPON SODA CO., LTD., number average molecular weight (Mn)=4300, styrene-butadiene block copolymer (styrene: 20%, 1,2 vinyl structure: 30%).

B3: trade name “Ricon100” manufactured by CRAY VALLEY, number average molecular weight (Mn)=4500, styrene-butadiene copolymer (1,2 vinyl structure: 70%).

### [Other Resin Components]

Trade name “L-DAIC” manufactured by SHIKOKU CHEMICALS CORPORATION, isocyanuric acid (diallylated isocyanuric acid derivative).

### [Component (C)]

C1: trade name “G1652” manufactured by Kraton Polymers, number average molecular weight (Mn): 54,000, thermoplastic elastomer (SEBS, styrene: 30%).

C2: trade name “P1500” manufactured by Asahi Kasei Corporation, number average molecular weight (Mn): 49,000, thermoplastic elastomer (SBBS, styrene: 30%).

C3: trade name “TR2003” manufactured by ENEOS Materials Corporation, number average molecular weight (Mn): 100,000, styrene-butadiene block copolymer (styrene: 43%).

### [Component (D)]

D1: trade name “PERCUMYL D” manufactured by NOF Corporation, organic peroxide.

### [Component (E)]

E1: trade name “20SV-C9” manufactured by Admatechs, silica filler (average particle diameter: 2 μm, vinylsilane surface-treated).

E2: trade name “SC4050SX” manufactured by Admatechs, silica filler (average particle diameter: 1 μm, aminosilane surface-treated).

E3: trade name “FB-3SDXHOL2” manufactured by Denka Company Limited, silica filler (average particle diameter: 3 μm, vinylsilane surface-treated).

The total amount (part by mass) of the component (A), the component (B), the component (C), and other resin components in the raw materials used in the preparation of the resin composition is shown in the column of “total resin component (A+B+C+other resin)” in Tables 1 to 4. The ratio (part by mass) of the component (E) to 100 parts by mass as the total of the component (A) and the component (B) used in the preparation of the resin composition is shown in the column of “filler amount (part by mass) with respect to 100 parts by mass as total of (A+B)” in Tables 2 and 3.

For the solutions containing the resin compositions in Examples 1 to 17 and Comparative Examples 1 to 7 obtained as described above, the “minimum melt viscosity (Pa·s)” and the “minimum melting temperature (° C.)” were measured by the following methods. The results are shown in Tables 1 to 4.

In addition, for the solutions containing the resin compositions in Examples 6 to 17 and Comparative Examples 3 to 7, “copper foil peel strength M (N/cm)” and “copper foil peel strength S (N/cm)” were measured by the following methods. The results are shown in Tables 2 to 4.

Further, for the solutions containing the resin compositions in Examples 6 to 8, the “dielectric constant (c)” and the “dielectric loss tangent (tan δ)” were evaluated and measured by the following method as the evaluation of “heat resistance reliability”. The results are shown in Table 4.

### [Preparation of Resin Film]

First, a solution containing a resin composition was applied onto a release-treated PET film by a knife method. Thereafter, the solution on the PET film was dried at a temperature of 80° C. to 130° C. to prepare a resin film having a thickness of 50 μm to 100 μm.

### [Minimum Melt Viscosity (Pa·s) and Minimum Melting Temperature (° C.)]

The prepared resin film was laminated so as to have a thickness of 300 μm, and the melt viscosity was measured by a rheometer. The minimum melt viscosity and the minimum melting temperature at this time were read, and the read values were defined as the minimum melt viscosity (Pa·s) and the minimum melting temperature (° C.) of the resin composition. The measurement was performed using a parallel plate having a diameter of 5 mm under conditions of a load of 50 gf, a strain of 1%, a frequency of 10 Hz, and a temperature range of 50° C. to 200° C. at 5° C./min.

### [Copper Foil Peel Strength M (N/cm)]

The prepared resin film was sandwiched between copper foil roughened surfaces having a thickness of 18 μm and cured at 200° C. for 60 minutes under a pressure of 1 MPa to prepare a double-sided copper clad sheet. The prepared double-sided copper clad sheet was cut into a width of 1 cm, and the strength when the copper foil on one side was peeled off in a 180° direction was measured. The measurement conditions were a tensile speed of 50 mm/min.

### [Copper Foil Peel Strength S (N/cm)]

The prepared resin film was sandwiched between copper foil smooth surfaces having a thickness of 18 μm and cured at 200° C. for 60 minutes under a pressure of 1 MPa to prepare a double-sided copper clad sheet. The prepared double-sided copper clad sheet was cut into a width of 1 cm, and the strength when the copper foil on one side was peeled off in a 180° direction was measured. The measurement conditions were a tensile speed of 50 mm/min.

### [Heat Resistance Reliability]

The prepared resin film was cured at 200° C. for 60 minutes under a pressure of 1 MPa to prepare a sample for heat resistance reliability evaluation. The dielectric constant (ε) and the dielectric loss tangent (tan δ) of the prepared sample were measured by a dielectric resonator method (SPDR method). Each value measured after the test piece was prepared as described above was set as an initial value before a heat resistance test. The results are shown in the column of “initial value” in Table 4. Next, the sample was placed in an oven heated to 125° C. for 24 hours, and then taken out from the oven and cooled to room temperature. The dielectric constant (ε) and the dielectric loss tangent (tan δ) of the sample cooled to room temperature were measured in the same manner as described above. The value measured in this manner is used as a measured value after the heat resistance test, and are shown in the column of “after 125° C. for 24 hours” in Table 4. In addition, for the values of the dielectric constant (ε) and the dielectric loss tangent (tan δ) measured before and after the heat resistance test, a value obtained by subtracting the initial value from the measured value after the heat resistance test was obtained as a “change amount with respect to initial value”. Further, the percentage of the value obtained by dividing the “change amount with respect to initial value” by the initial value was obtained as a “change amount (%) with respect to initial value”. The results are shown in Table 4. In the measurement by the dielectric resonator method, the measurement frequency was set to 20 GHz.

For some examples of Examples 6 to 17 and Comparative Examples 3 to 7, “thermal expansion coefficient (ppm/K)”, “thermal expansion coefficient (thickness) (ppm/K)”, and “solder heat resistance” were evaluated and measured by the following methods. In addition, for Examples 6 to 16 and Comparative Examples 3 to 7, the initial values of the dielectric constant (ε) and the dielectric loss tangent (tan δ) in the heat resistance reliability described above were measured. Further, for Examples 9 to 16 and Comparative Examples 3 to 7, the initial values of the dielectric constant (ε) and the dielectric loss tangent (tan δ) in the heat resistance reliability described above were measured by changing the measurement frequency to 10 GHz in the dielectric resonator method.

[Thermal Expansion Coefficient (ppm/K)] The prepared resin film was laminated so as to have a thickness of 100 μm, and cured at a temperature of 200° C. for 60 minutes under a pressure of 1 MPa to prepare a sample for measuring the thermal expansion coefficient. The prepared sample was subjected to measurement by a tensile method using a thermomechanical analyzer (TMA), and an average thermal expansion coefficient at 90° C. to 100° C. was set as a read value (that is, a measured value of the thermal expansion coefficient). The measurement was performed by annealing to 230° C. under conditions of a tensile load of 2 gf at 20° C./min, then returning to room temperature, and then to 230° C. at 5° C./min. The measured thermal expansion coefficient is a thermal expansion coefficient in a plane direction (that is, XY direction).

### [Thermal Expansion Coefficient (Thick) (Ppm/K)]

The prepared resin film was laminated so as to have a thickness of about 2 mm, and cured at a temperature of 200° C. for 60 minutes under a pressure of 1 MPa to prepare a sample for measuring the thermal expansion coefficient (thick). The prepared sample was subjected to measurement by a compression method using a thermomechanical analyzer (TMA), and an average thermal expansion coefficient at 90° C. to 100° C. was set as a read value (that is, a measured value of the thermal expansion coefficient (thick)). The measurement was performed by annealing to 250° C. under conditions of a compression load of 1 gf at 20° C./min, then returning to room temperature, and then to 250° C. at 5° C./min. The thermal expansion coefficient is a thermal expansion coefficient in a thickness direction (that is, a Z direction).

### [Solder Heat Resistance]

A copper foil was bonded to both surfaces of the prepared adhesive film, and then cut into a square of 2 cm×2 cm to prepare a test piece. The prepared test piece was floated for 1 minute in solder baths heated to 260° C., 270° C., 280° C., 290° C., and 300° C., and the appearance thereof was visually checked. The temperature (maximum temperature) of the solder bath at which no change in appearance was observed was defined as an evaluation value for the solder heat resistance.

TABLE 1

| | | Comparative | Comparative | | | | | |
|---|---|---|---|---|---|---|---|---|
| | | Example 1 | Example 2 | Example 1 | Example 2 | Example 3 | Example 4 | Example 5 |
| Component (A) | A1(1) | — | — | — | — | — | — | — |
| | A1(2) | — | — | 33.3 | 33.3 | 33.3 | — | 33.3 |
| | A1′ | 35.4 | 33.3 | — | — | — | — | — |
| | A2(1) | — | — | 8.3 | — | — | — | — |
| | A2(2) | — | — | — | — | — | 33.3 | — |
| Component (B) | B1(1) | — | — | — | 8.3 | — | — | — |
| | B1(2) | — | — | — | — | — | — | — |
| | B1(3) | 22.9 | — | — | — | — | — | — |
| | B2(1) | — | 25.0 | 16.7 | 16.7 | 16.7 | 25.0 | 25.0 |
| | B2(2) | — | — | — | — | — | — | — |
| | B3 | — | — | — | — | — | — | — |
| Other resin components | | — | — | — | — | 8.3 | — | — |
| Component (C) | C1 | — | 41.7 | 41.7 | 41.7 | 41.7 | 41.7 | 41.7 |
| | C2 | 41.7 | — | — | — | — | — | — |
| | C3 | — | — | — | — | — | — | — |
| Component (D) | D1 | 0.83 | 1.67 | 1.67 | 1.67 | 1.67 | 1.67 | 1.67 |
| Total resin component | | 100 | 100 | 100 | 100 | 100 | 100 | 100 |
| (A + B + C + other resin) | | | | | | | | |
| Minimum melt | Pa · s | Cannot be | 6039 | 1629 | 1765 | 1765 | 2415 | 1601 |
| viscosity | | measured | | | | | | |
| Minimum | ° C. | Cannot be | 142 | 124 | 128 | 128 | 138 | 127 |
| melting | | measured | | | | | | |
| temperature | | | | | | | | |

TABLE 2

| | | Comparative | Comparative | Comparative | Comparative | Comparative | | |
|---|---|---|---|---|---|---|---|---|
| | | Example 3 | Example 4 | Example 5 | Example 6 | Example 7 | Example 9 | Example 10 |
| Component | A1(1) | — | — | — | — | 35.0 | — | — |
| (A) | A1(2) | — | — | — | — | — | 48.0 | 48.0 |
| | A1′ | 35.4 | 35.4 | 35.4 | 35.4 | — | — | — |
| | A2(1) | — | — | — | — | — | — | — |
| | A2(2) | — | — | — | — | — | — | — |
| Component | B1(1) | — | — | — | — | — | 20.0 | — |
| (B) | B1(2) | — | — | — | — | — | — | 20.0 |
| | B1(3) | — | — | — | — | — | — | — |
| | B2(1) | — | — | — | 22.9 | — | — | — |
| | B2(2) | — | — | 22.9 | — | — | — | — |
| | B3 | 22.9 | — | — | — | — | — | — |
| Other resin | | — | — | — | — | — | — | — |
| components | | | | | | | | |
| Component | C1 | 41.7 | 41.7 | 41.7 | 41.7 | 65.0 | — | — |
| (C) | C2 | — | — | — | — | — | 32.0 | 32.0 |
| | C3 | — | 22.9 | — | — | — | — | — |
| Component | D1 | 1.67 | 1.67 | 1.67 | 1.67 | 0.9 | 0.5 | 0.5 |
| (D) | | | | | | | | |
| Component | E1 | 312.5 | 312.5 | 312.5 | 312.5 | — | — | — |
| (E) (filer) | E2 | — | — | — | — | — | 146.7 | 146.7 |
| | E3 | — | — | — | — | 311.0 | — | — |
| Total resin | | 100 | 100 | 100 | 100 | 100 | 100 | 100 |
| component | | | | | | | | |
| (A + B + C + other resin) | | | | | | | | |
| Filer amount (part | | 636.0 | 882.8 | 536.0 | 536.0 | 888.6 | 215.7 | 215.7 |
| by mass) with | | | | | | | | |
| respect to 100 parts | | | | | | | | |
| by mass as total of | | | | | | | | |
| (A + B) | | | | | | | | |
| Minimum | Pa · s | 42070 | 72970 | 550042 | 40604 | 362428 | 11983 | 17439 |
| melt | | | | | | | | |
| viscosity | | | | | | | | |
| Minimum | ° C. | 138 | 159 | 147 | 138 | 170 | 137 | 132 |
| melting | | | | | | | | |
| temperature | | | | | | | | |
| Peel | N/cm | 7.0 | 1.9 | 7.1 | 5.7 | 6.6 | 3.6 | 3.8 |
| strength M | | | | | | | | |
| Peel | N/cm | 0.4 | 0.0 | 1.9 | 0.6 | 4.5 | | |
| strength S | | | | | | | | |

TABLE 3

| | | Example 11 | Example 12 | Example 13 | Example 14 | Example 15 | Example 16 | Example 17 |
|---|---|---|---|---|---|---|---|---|
| Component (A) | A1(1) | — | — | — | 35.4 | — | — | — |
| | A1(2) | 35.4 | 20.8 | 45.0 | — | 35.4 | 35.4 | 80.0 |
| | A1′ | — | — | — | — | — | — | — |
| | A2(1) | — | — | — | — | — | — | — |
| | A2(2) | — | — | — | — | — | — | — |
| Component (B) | B1(1) | — | — | — | — | — | — | — |
| | B1(2) | — | — | — | — | — | — | — |
| | B1(3) | — | — | — | — | — | — | — |
| | B2(1) | 22.9 | 37.5 | 5.0 | 22.9 | — | — | 20.0 |
| | B2(2) | — | — | — | — | — | 22.9 | — |
| | B3 | — | — | — | — | 22.9 | — | — |
| Other resin components | | — | — | — | — | — | — | — |
| Component (C) | C1 | 41.7 | 41.7 | 50.0 | 41.7 | 41.7 | 41.7 | — |
| | C2 | — | — | — | — | — | — | — |
| | C3 | — | — | — | — | — | — | — |
| Component (D) | D1 | 1.7 | 1.7 | 2.0 | 1.7 | 1.7 | 1.7 | 0.8 |
| Component (E) | E1 | 312.5 | 312.5 | 375.0 | 312.5 | 312.5 | 312.5 | — |
| (filler) | E2 | — | — | — | — | — | — | — |
| | E3 | — | — | — | — | — | — | — |
| Total resin component | | 100 | 100 | 100 | 100 | 100 | 100 | 100 |
| (A + B + C + other resin) | | | | | | | | |
| Filler amount (part by mass) with | | 536.0 | 536.0 | 750.0 | 536.0 | 536.0 | 536.0 | 0.0 |
| respect to 100 parts by mass as | | | | | | | | |
| total of (A + B) | | | | | | | | |
| Minimum melt | Pa · s | 10611 | 8412 | 25998 | 22203 | 10244 | 24841 | 658 |
| viscosity | | | | | | | | |
| Minimum melting | ° C. | 125 | 128 | 125 | 132 | 124 | 127 | 100 |
| temperature | | | | | | | | |
| Peel strength M | N/cm | 6.2 | 4.8 | 8.0 | 4.9 | 4.1 | 1.4 | 5.4 |
| Peel strength S | N/cm | 1.7 | 3.0 | 1.0 | 1.3 | 1.4 | 3.6 | 0.1 |

TABLE 4

| | | | Example 6 | Example 7 | Example 8 |
|---|---|---|---|---|---|
| Component (A) | | A1(1) | — | — | — |
| | | A1(2) | 33.3 | 33.3 | 33.3 |
| | | A1' | — | — | — |
| | | A2(1) | — | — | — |
| | | A2(2) | — | — | — |
| Component (B) | | B1(1) | — | — | — |
| | | B1(2) | — | — | 25.0 |
| | | B1(3) | — | — | — |
| | | B2(1) | 25.0 | — | — |
| | | B2(2) | — | — | — |
| | | B3 | — | 25.0 | — |
| Other resin components | | | — | — | — |
| Component (C) | | C1 | 41.7 | 41.7 | 41.7 |
| | | C2 | — | — | — |
| | | C3 | — | — | — |
| Component (D) | | D1 | 1.7 | 1.7 | 1.7 |
| Total resin component (A + B + C + other resin) | | | 100 | 100 | 100 |
| Minimum melt viscosity | | Pa · s | 1601 | 1711 | 3365 |
| Minimum melting temperature | | ° C. | 127 | 127 | 128 |
| Peel strength M | | N/cm | 8.1 | 7.8 | 5.8 |
| Peel strength S | | N/cm | 1.8 | 2.5 | 0.2 |
| Heat | Dielectric | Initial value | 2.43 | 2.44 | 2.41 |
| resistance | constant (ε) | After 125° C. for 24 hours | 2.37 | 2.35 | 2.30 |
| reliability | | Change amount with | −0.06 | −0.09 | −0.11 |
| | | respect to initial value | | | |
| | | Rate of change (%) with | −2% | −4% | −5% |
| | | respect to initial value | | | |
| | Dielectric loss | Initial value | 0.0014 | 0.0014 | 0.0015 |
| | tangent | After 125° C. for 24 hours | 0.0015 | 0.0020 | 0.0017 |
| | (tanδ) | Change amount with | 0.0001 | 0.0006 | 0.0002 |
| | | respect to initial value | | | |
| | | Rate of change (%) with | 7% | 43% | 13% |
| | | respect to initial value | | | |

### [Results]

As shown in Table 1, the resin compositions in Examples 1 to 5 have a lower minimum melt viscosity and a lower minimum melting temperature than those of the resin composition in Comparative Example 2. Note that, the minimum melt viscosity and the minimum melting temperature of the resin composition in Comparative Example 1 cannot be measured.

As shown in Tables 2 and 3, the resin compositions in Examples 9 to 17 have an extremely lower minimum melt viscosity than that of the resin compositions in Comparative Examples 3 to 7. In particular, the resin compositions in Examples 9 to 16 and Comparative Examples 3 to 7 contain an inorganic filler (silica filler) as the component (E), and the resin composition in Comparative Examples 3 to 7 have a very high minimum melt viscosity. On the other hand, since the resin compositions in Examples 9 to 16 contain a thermosetting resin having at least one of a vinylbenzyl group and a maleimide group as the component (A), an increase in minimum melt viscosity is prevented, and the resin compositions have excellent embeddability into a substrate.

In addition, the resin compositions in Examples 9 to 17 exhibit good values for the copper foil peel strength M (N/cm) and the copper foil peel strength S (N/cm), and have excellent adhesiveness. In addition, the resin compositions in Examples 9 to 16 exhibit good results for the thermal expansion coefficient and the solder heat resistance. For example, in the resin compositions in Examples 9 to 16, the thermal expansion coefficient (ppm/K) is sequentially 102, 123, 46, 50, 56, 44, 50, and 55 (all units are ppm/K). In addition, in the resin compositions in Examples 9 to 16, the thermal expansion coefficient (thick) (ppm/K) is 39, 55, 46, 56, 50, 38, 42, and 59 (all units are ppm/K).

In the resin compositions in Examples 9 to 14, at a measurement frequency of 10 GHz, the dielectric constant (ε) is sequentially 3.05, 3.12, 3.10, 3.10, 2.89, and 3.06, and the dielectric loss tangent (tan δ) is sequentially 0.0014, 0.0015, 0.0013, 0.0011, 0.0015, and 0.0014. In the resin compositions in Examples 13 to 16, at a measurement frequency of 20 GHz, the dielectric constant (ε) is sequentially 3.01, 3.08, 3.07, and 3.09, and the dielectric loss tangent (tan δ) is sequentially 0.0016, 0.0015, 0.0015, and 0.0013. In addition, the resin compositions in Examples 9 to 14 also exhibit a good value of 300° C. or 290° C. in the evaluation of solder heat resistance.

The resin composition in Example 17 is a resin composition not containing other resin components and containing the component (A) and the component (B) as the resin components. In addition, the resin composition in Example 17 does not contain an inorganic filler as the component (E). Such a resin composition in Example 17 also has a low minimum melt viscosity and a low minimum melting temperature. The resin composition in Example 17 has a thermal expansion coefficient (ppm/K) of 102 ppm/K and a thermal expansion coefficient (thick) (ppm/K) of 73 ppm/K. The resin composition in Example 17 can also be suitably used as, for example, a dielectric layer in a rewiring layer of a fan-out wafer level package (FO-WLP).

On the other hand, in the resin compositions in Comparative Examples 3 to 7, the thermal expansion coefficient (ppm/K) is sequentially 51, 35, 36, 51, and 50, and the thermal expansion coefficient (thick) (ppm/K) is sequentially 37, 47, 29, 37, and 64 (all units are ppm/K). In addition, in the resin compositions in Comparative Examples 3 to 7, at a measurement frequency of 10 GHz, the dielectric constants (E) is sequentially 3.12, 3.06, 3.11, 3.12, and 3.12, and the dielectric loss tangents (tan δ) is sequentially 0.0014, 0.0012, 0.0013, 0.0014, and 0.0019. In addition, the resin composition in Comparative Example 7 exhibits a low value of 270° C. in the evaluation of solder heat resistance.

As shown in Table 4, in the resin composition in Example 6, the styrene-butadiene block copolymer as the component (B2) is used as the component (B). In the resin composition in Example 8, the butadiene resin as the component (B1) is used as the component (B). In the resin composition in Example 7, the styrene-butadiene copolymer as the component (B3) is used as the component (B). In the case of comparing the resin compositions in Examples 6 to 8 to one another, the resin composition in Example 6 using a styrene-butadiene block copolymer as the component (B2) exhibits better heat resistance reliability (rate of change in tan δ) and better peel strength M with respect to a matte surface (M surface) of an electrolytic copper foil than other components (B). In the resin compositions in Examples 6 to 8, the thermal expansion coefficient (ppm/K) is sequentially 149, 146, and 154, and the thermal expansion coefficient (thick) (ppm/K) is sequentially 194, 207, and 196 (all units are ppm/K).

### INDUSTRIAL APPLICABILITY

The resin composition according to the present invention can be used as a resin composition for an adhesive or an adhesive film used for an electronic component. In addition, the resin composition according to the present invention can also be used as an interlayer bonding sheet or an interlayer adhesive for a multilayer wiring board. Further, the resin composition according to the present invention can also be used as a prepreg using a cured product of the resin composition or as a high-frequency electronic component containing a cured product of the resin composition.

1. A resin composition comprising:
(A) a thermosetting resin having at least one of a vinylbenzyl group and a maleimide group; and
(B) a compound having a butadiene skeleton having a 1,2 vinyl group, wherein the component (B) has a number average molecular weight of 1,000 to 10,000.

2. The resin composition according to claim 1, wherein the resin composition has a minimum melt viscosity of less than 40,000 Pa·s.

3. The resin composition according to claim 1, wherein the component (A) is a thermosetting resin having a vinylbenzyl group at its terminal and having a polyphenylene skeleton.

4. The resin composition according to claim 1, wherein the component (B) is a compound having a styrene skeleton.

5. The resin composition according to claim 1, wherein the component (B) is a styrene-butadiene block copolymer.

6. The resin composition according to claim 1, wherein the component (B) is a styrene-butadiene-styrene block copolymer represented by the following structural formula (1) or a hydrogenated product thereof: 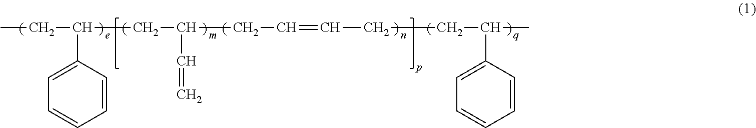
(in the structural formula (1), m, o, p, and q are each independently a positive integer, n is 0 or a positive integer, a relationship of o:p:q=(1 to 20):(60 to 98):(1 to 20) is satisfied, and a relationship of m:n=100:0 to 80:20 is satisfied).

7. The resin composition according to claim 1, wherein the butadiene skeleton of the component (B) contains 5 mass % to 95 mass % of a 1,2 vinyl structure.

8. The resin composition according to claim 1, further comprising:
(C) a thermoplastic elastomer component.

9. The resin composition according to claim 1, further comprising:
(D) a reaction accelerator component.

10. The resin composition according to claim 9, wherein the component (D) is an organic peroxide.

11. The resin composition according to claim 1, further comprising:
(E) an inorganic filler.

12. The resin composition according to claim 11, wherein the component (E) is contained in an amount of 50 mass % or more in 100 mass % of a non-volatile component in the resin composition.

13. The resin composition according to claim 11, wherein the component (E) is contained in an amount of 200 parts by mass or more with respect to 100 parts by mass as a total of the component (A) and the component (B).

14. The resin composition according to claim 1, wherein the component (B) is contained in an amount of 10 to 200 parts by mass with respect to 100 parts by mass of the component (A).

15. (canceled)

16. An adhesive film for interlayer insulation, comprising:
the resin composition according to claim 1.

17. A laminated substrate comprising:
a cured product of the resin composition according to claim 1.

18. An electronic component comprising:
the laminated substrate according to claim 17.

19. A semiconductor device comprising:
the laminated substrate according to claim 17.

20. A laminated substrate comprising:
a cured product of the adhesive film for interlayer insulation according to claim 16.

21. A semiconductor device comprising:
the electronic component according to claim 18.
